(19) United States
(12) Patent Application Publication
(10) Pub. No.: US 2025/0379125 A1
(43) Pub. Date: Dec. 11, 2025

(54) DOUBLE-SIDED POWER DEVICE AND METHOD FOR MANUFACTURING THE SAME

(71) Applicant: NIKO SEMICONDUCTOR CO., LTD., NEW TAIPEI CITY (TW)

(72) Inventors: Hui-Chiang Yang, TAIPEI HSIEN (TW); CHUNG-MING LENG, New Taipei City (TW); CHIH-CHENG HSIEH, Taoyuan City (TW); Wei-Lun Wang, NEW TAIPEI CITY (TW); PIN-RUI HUANG, New Taipei City (TW)

(21) Appl. No.: 18/928,427

(22) Filed: Oct. 28, 2024

(30) Foreign Application Priority Data
Jun. 7, 2024 (TW) 113121136

(51) Int. Cl. H01L 23/495; H01L 23/00; H01L 23/31; H01L 25/00; H01L 25/065

(52) U.S. Cl. CPC H01L 23/49517; H01L 23/3107; H01L 23/49575; H01L 25/0657; H01L 25/50; H01L 23/49568; H01L 24/40; H01L 2224/40245; H01L 2225/06572

(57) ABSTRACT

A double-sided power device and a method for manufacturing the double-sided power device are provided. The double-sided power device includes a first power module, a second power module, two support members, and an encapsulant. The first power module includes a first power chip. The second power module includes a second power chip. The first power module is opposite to the second power module, and a packaging space is defined between the first power module and the second power module. The two support members are located in the packaging space to be connected to the first power module and the second power module, respectively. The encapsulant is filled in the packaging space.

### CROSS-REFERENCE TO RELATED PATENT APPLICATION

This application claims the benefit of priority to Taiwan Patent Application No. 113121136, filed on Jun. 7, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a power module, and more particularly to a power module having a double-sided circuit substrate structure.

### BACKGROUND OF THE DISCLOSURE

Power modules include circuit substrate components, and can be used in household inverter systems, electric vehicles, and industrial control systems to convert electrical energy or control circuits.

In the existing technology, the power provided by a single power module is limited. If the power that is output needs to increase, multiple power modules needs to be connected in series, thus increasing the space required for power module installation, which is not conducive to size reduction. In addition, for high-power modules, the improvement for heat-dissipation effect is also one of the important issues.

Therefore, how to increase the output capability of the power module and enhance the heat-dissipation capability through structural design improvements to improve the above-mentioned defects has become one of the important issues to be addressed in this business.

### SUMMARY OF THE DISCLOSURE

In response to the above-referenced technical inadequacies, the present disclosure provides a double-sided power device and a method for manufacturing the double-sided power device.

In order to solve the above-mentioned problems, one of the technical aspects adopted by the present disclosure is to provide a double-sided power device. The double-sided power device includes a first power module, a second power module, at least two support members, and an encapsulant. The first power module includes a first circuit substrate, a first conductive layer, a first power chip, a second conductive layer, and a first electrical connecting element. The first conductive layer is located on the first circuit substrate. The first power chip is located on the first conductive layer. The second conductive layer is located on the first circuit substrate and spaced apart from the first conductive layer by a first gap. The first conductive layer and the second conductive layer have different electrical potentials. Two ends of the first electrical connecting element are electrically connected to the first power chip and the second conductive layer, respectively. The second power module is opposite to the first power module, a packaging space is defined between the first power module and the second power module, and the second power module includes a second circuit substrate, a third conductive layer, a second power chip, a fourth conductive layer, and a second electrical connecting element. The third conductive layer is located on the second circuit substrate. The second power chip is located on the third conductive layer. The fourth conductive layer is located on the second circuit substrate and spaced apart from the third conductive layer by a second gap. Two ends of the second electrical connecting element are electrically connected to the second power chip and the fourth conductive layer, respectively. The at least two support members are respectively defined as a first support member and a second support member. Two ends of the first support member are electrically connected to the first conductive layer and the third conductive layer, respectively, and two ends of the second support member are electrically connected to the second conductive layer and the fourth conductive layer, respectively. The encapsulant is filled in the packaging space.

In one of the possible or preferred embodiments, each of the support members is a column or a wall.

In one of the possible or preferred embodiments, each of the support members is made of metal.

In one of the possible or preferred embodiments, each of the support members is a tin pillar, and a length of each of the support members in a vertical direction is greater than or equal to 0.5 mm.

In one of the possible or preferred embodiments, the each of the support members can withstand a current flow of at least 5 amps.

In one of the possible or preferred embodiments, a cross-sectional area of each of the support members in a horizontal cross-section occupies 1% to 5% of an area of the first circuit substrate.

In one of the possible or preferred embodiments, a horizontal plane is defined between the first power module and the second power module, and the first power module is mirror-symmetrical to the second power module via the horizontal plane.

In one of the possible or preferred embodiments, a projection of the first power chip on the second circuit substrate along a vertical direction defines a projection area, and at least a portion of the second power chip is not located within the projection area.

In order to solve the above-mentioned problems, another one of the technical aspects adopted by the present disclosure is to provide a method for manufacturing a double-sided power device. The method includes the following steps: providing a first power module; the first power module includes a first circuit substrate, a first conductive layer, a first power chip, a second conductive layer, and a first electrical connecting element; the first conductive layer is located on the first circuit substrate; the first power chip is located on the first conductive layer; the second conductive layer is located on the first circuit substrate and spaced apart from the first conductive layer by a first gap; the first conductive layer and the second conductive layer have different electrical potentials; two ends of the first electrical connecting element are electrically connected to the first power chip and the second conductive layer, respectively; disposing at least two support members; the at least two support members are respectively defined as a first support member and a second support member, and one end of the first support member is connected to the first conductive layer, and one end of the second support member is connected to the second conductive layer; disposing a second power module; the second power module is opposite to the first power module, a packaging space is defined between the first power module and the second power module, and the second power module includes: a second circuit substrate, a third conductive layer, a second power chip, a fourth conductive layer, and a second electrical connecting element; the third conductive layer is located on the second circuit substrate; the second power chip is located on the third conductive layer; the fourth conductive layer is located on the second circuit substrate and spaced apart from the third conductive layer by a second gap; two ends of the second electrical connecting element are electrically connected to the second power chip and the fourth conductive layer, respectively; another end of the first support member is connected to the third conductive layer, and another end of the second support member is connected to the fourth conductive layer; filling an encapsulant into the packaging space.

Therefore, in the double-sided power device and the method for manufacturing the double-sided power device provided by the present disclosure, by the structural design of the double-sided power device, the support members having electrical conductivity are disposed in the power device, such that the first power module and the second power module are electrically connected. Therefore, the power output by the power modules can be increased in a unit area; for example, the power output can be doubled.

Furthermore, by providing the support members, heights of the first power module and the second power module in the vertical direction can be limited.

Moreover, according to certain embodiments, since the support members are metal column or metal walls, the structural strength of the double-sided power device can be enhanced.

In addition, according to certain embodiments, since the support members are metal column or metal walls, the heat-dissipation capability of the double-sided power device can be improved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1A is a schematic exploded view of a double-sided power device according to one embodiment of the present disclosure;

FIG. 1B is a schematic view of the embodiment of FIG. 1A;

FIG. 1C is a schematic side view of the embodiment of FIG. 1A;

FIG. 2 is a schematic side view of a double-sided power device according to one embodiment of the present disclosure;

FIG. 3A is a schematic view of a double-sided power device according to one embodiment of the present disclosure;

FIG. 3B is a schematic side view of the embodiment shown in FIG. 3A;

FIG. 4 is a schematic top view of a double-sided power device according to one embodiment of the present disclosure, in which only a second circuit substrate and a plurality of support members are shown;

FIG. 5 is a side view of a double-sided power device according to one embodiment of the present disclosure; and

FIG. 6 is a schematic flowchart of a method for manufacturing a double-sided power device according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

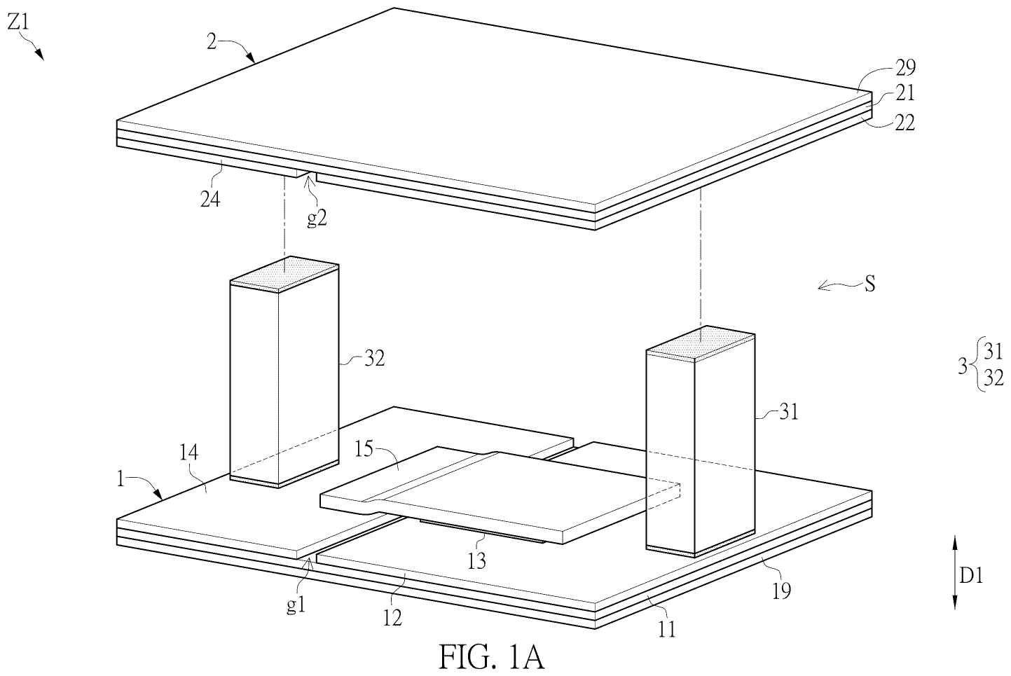

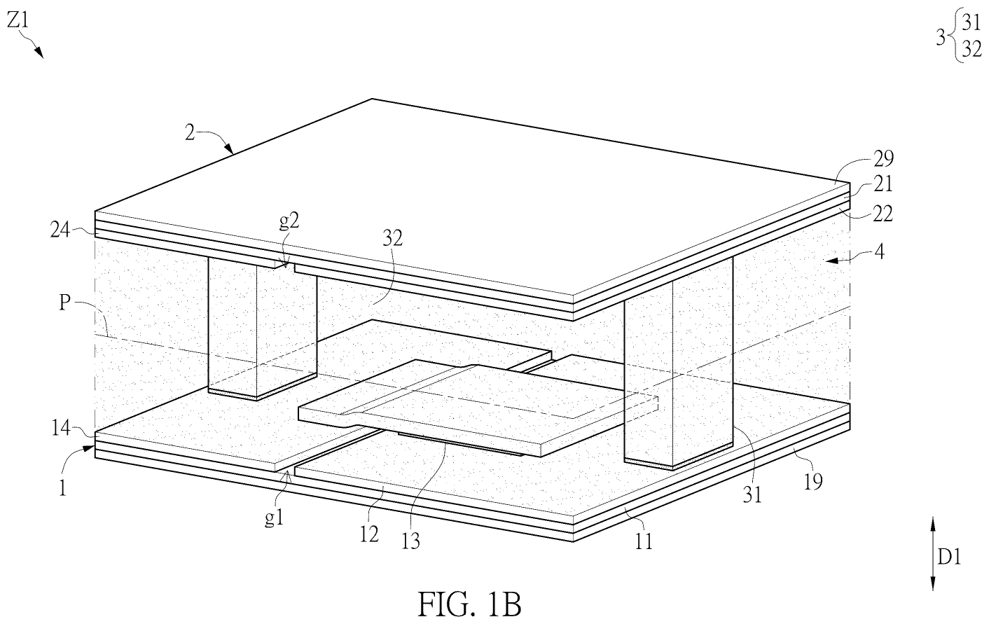

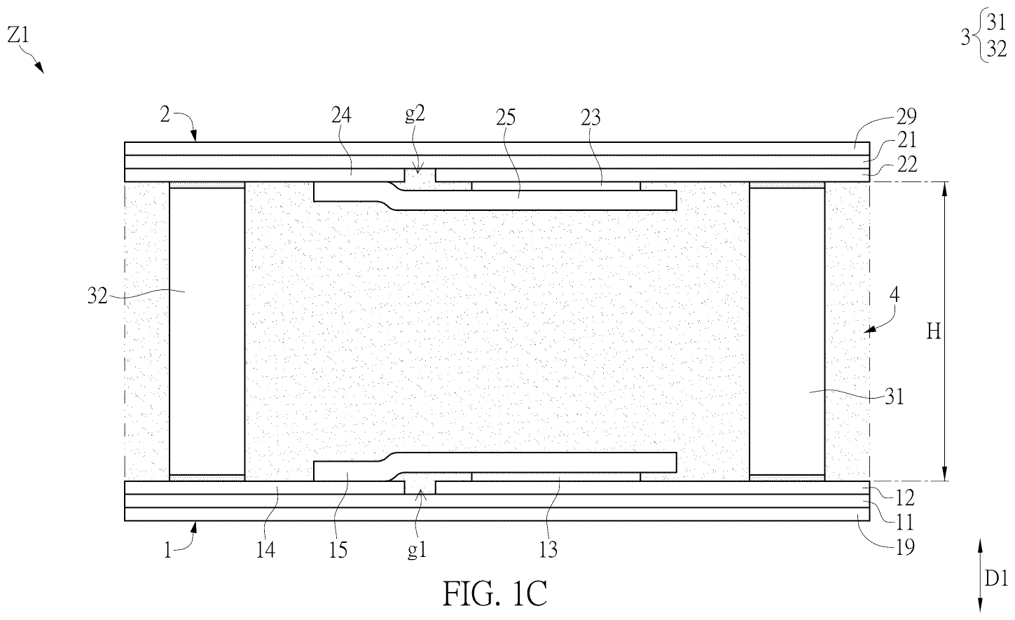

Referring to FIG. 1A to FIG. 1C, FIG. 1A is a schematic exploded view of a double-sided power device according to one embodiment of the present disclosure, in which an encapsulant 4 is omitted; FIG. 1B is a schematic view of the embodiment of FIG. 1A, and FIG. 1C is a schematic side view of the embodiment of FIG. 1A.

A double-sided power device Z1 includes a first power module 1, a second power module 2, two support members 3, and an encapsulant 4. The first power module 1 includes a first circuit substrate 11, a first conductive layer 12, a first heat-dissipation layer 19, a first power chip 13, a second conductive layer 14, and a first electrical connecting element 15. The first conductive layer 12 is located on the first circuit substrate 11. The first power chip 13 is located on the first conductive layer 12. The second conductive layer 14 is located on the first circuit substrate 11 and spaced apart from the first conductive layer 12 by a first gap g1. The first conductive layer 12 and the second conductive layer 14 have different electrical potentials. Two ends of the first electrical connecting element 15 are electrically connected to the first power chip 13 and the second conductive layer, 14 respectively. The first circuit substrate 11 may be, but is not limited to, a ceramic substrate. According to certain embodiments, the first conductive layer 12 and the second conductive layer 14 are copper foils deposited on the first circuit substrate 11 by sputtering. In this embodiment, the first electrical connecting element 15 is a conductive film layer, such as copper foil.

The second power module 2 is opposite to the first power module 1, and a packaging space S is defined between the second power module 2 and the first power module 1. The second power module 2 includes a second circuit substrate 21, a third conductive layer 22, a second heat-dissipation layer 29, a second power chip 23, the fourth conductive layer 24, and the second electrical connecting element 25. The third conductive layer 22 is located on the second circuit substrate 21. The second power chip 23 is located on the third conductive layer 22. The fourth conductive layer 24 is located on the second circuit substrate 21 and spaced apart from the third conductive layer 22 by a second gap g2. Two ends of the second electrical connecting element 25 are electrically connected to the second power chip 23 and the fourth conductive layer 24, respectively. The second circuit substrate 21 may be, but is not limited to, a ceramic substrate. According to certain embodiments, the third conductive layer 22 and the fourth conductive layer 24 are copper foils. In this embodiment, the second electrical connecting element 25 is also a conductive film layer, such as copper foil.

In this embodiment, the quantity of the support members 3 is two. The support members 3 may be electrically conductive. In this embodiment, the two support members 3 are respectively defined as a first support member 31 and a second support member 32. Two ends of the first support member 31 are electrically connected to the first conductive layer 12 and the third conductive layer 22, respectively, and two ends of the second support member 32 are electrically connected to the second conductive layer 14 and the fourth conductive layer 24, respectively. In the embodiment shown in FIG. 1A, the support members 3 are columns, which may be cylinders columns or square columns, and are represented by square columns herein. However, the present disclosure is not limited thereto. According to certain embodiments, the support members 3 may also be walls (or wall surfaces). In certain embodiments, the support members 3 are made of metal, such as copper. In this embodiment, two ends of each of the support members 3 are connected to the first power module 1 and the second power module 2 through a solder paste. However, the present disclosure is not limited thereto. According to certain embodiments, the support members 3 are connected to the first power module 1 and the second power module 2 respectively through ultrasonic bonding. According to certain embodiments, the support member 3 can also be connected to the first power module 1 and the second power module 2 respectively through soldering. In certain embodiments, the support members 3 are tin columns (square columns or cylinder columns), and a length of the support members 3 in a vertical direction D1 is greater than or equal to 0.5 mm. In certain embodiments, the length of the support members 3 in the vertical direction D1 ranges from 1.0 mm to 3.0 mm, which is configured depending on the power specifications required by the manufacturer. It should be noted that, the support members 3 are used as power devices, and each of the support members 3 can withstand a current flow of at least 5 amps.

The encapsulant 4 is filled in the packaging space S. The encapsulant 4 is, for example, but not limited to epoxy.

In this embodiment, the junction between a lower surface of the first power chip 13 and the first conductive layer 12 is the source electrode, and the junction between an upper surface of the first power chip 13 and the first electrical connecting element 15 is the drain electrode. The junction between a lower surface of the second power chip 23 and the third conductive layer 22 is the source electrode, and the junction between an upper surface of the second power chip 23 and the second electrical connecting element 25 is the drain electrode. The same potentials are connected via the support members 3. According to the embodiment shown in FIG. 1B, doubling the power output for a unit area (for example, based on an area of the first circuit substrate 11) can be achieved.

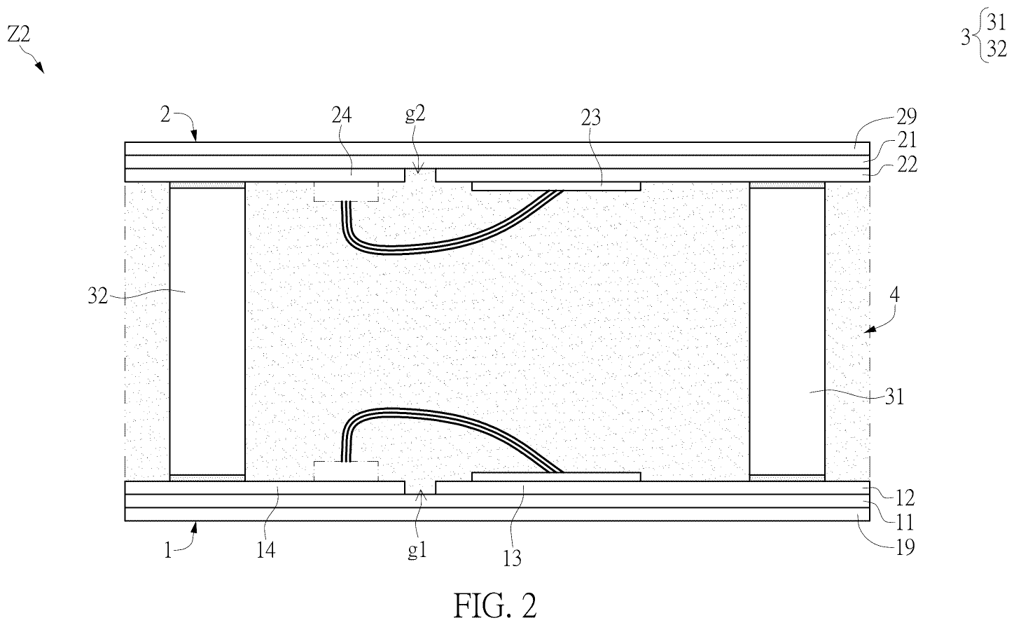

Referring to FIG. 2, FIG. 2 is a schematic side view of a double-sided power device Z2 according to one embodiment of the present disclosure. In this embodiment, the first power chip 13 and the second power chip 23 are electrically connected to the second conductive layer 14 and the fourth conductive layer 24 through wire bonding, respectively. In other words, a manner of bonding in the double-sided power device of the present disclosure is not limited to flip-chip, and may also be wire bonding.

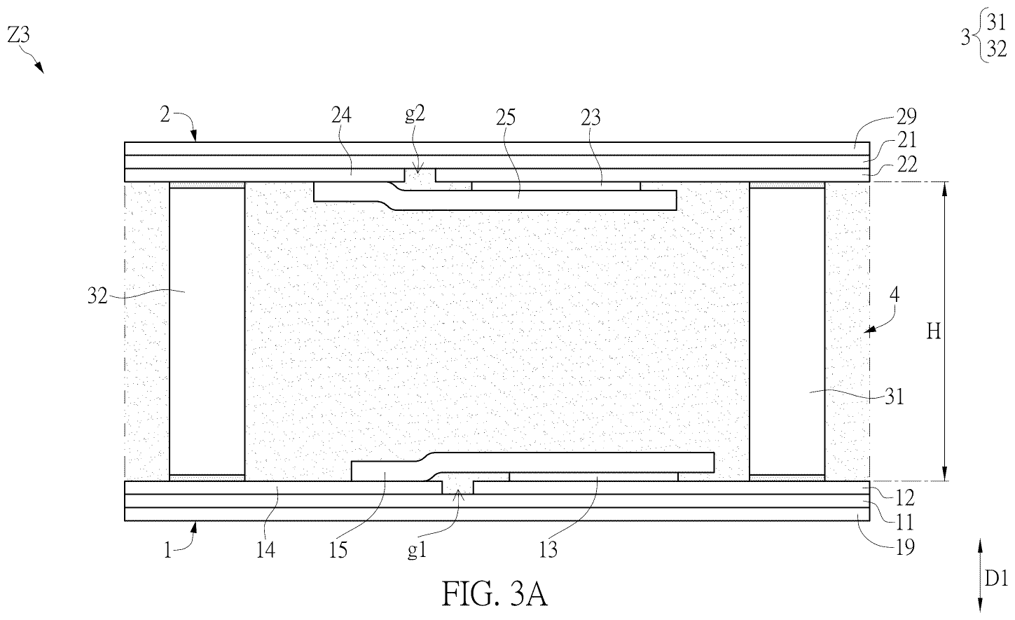

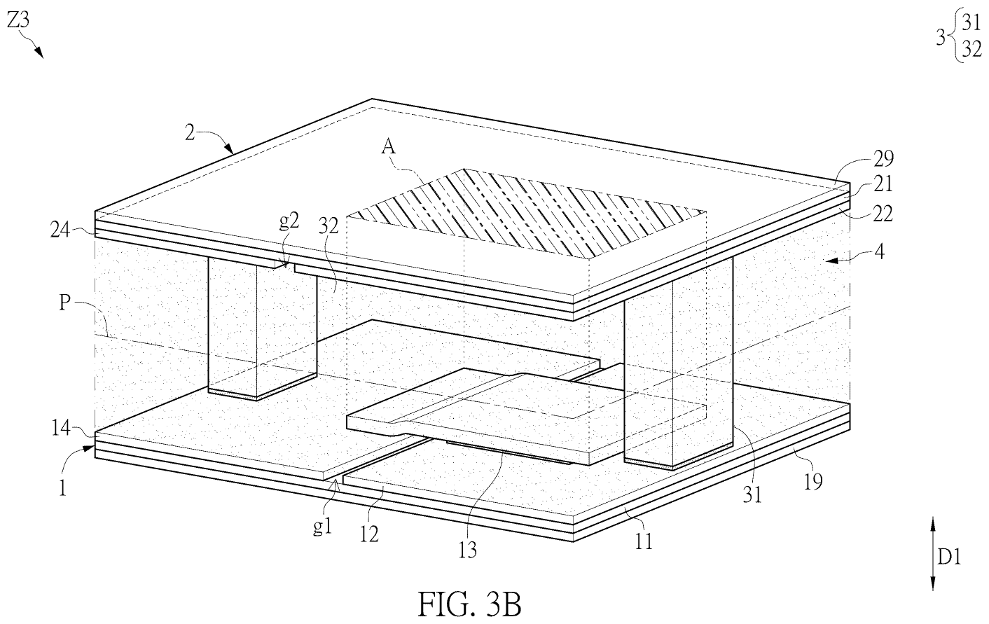

Referring to FIG. 3A and FIG. 3B, FIG. 3A is a schematic view of a double-sided power device Z3 according to one embodiment of the present disclosure, and FIG. 3B is a schematic side view of the embodiment shown in FIG. 3A. A horizontal plane P is defined between the first power module 1 and the second power module 2, and the first power module 1 is mirror-symmetrical to the second power module 2 via the horizontal plane P. In other words, the double-sided power device of the present disclosure includes a first power module 1 and a second power module 2. The first power module 1 and the second power module 2 can be bonded in a symmetrical manner (as shown in FIG. 1C). However, the present disclosure is not limited thereto. According to the embodiment shown in FIG. 3A, the first power module 1 and the second power module 2 can also be bonded in an asymmetric manner (as shown in FIG. 3B). In the embodiment shown in FIG. 3A, a projection of the first power chip 13 on the second circuit substrate 21 along the vertical direction D1 defines a projection area A, and at least a portion of the second power chip 23 is not located within the projection area A. For example, when projected on the horizontal plane in the vertical direction D1, the projections of the first power chip 13 and the second power chip 23 are completely not overlapped with each other (i.e., the projections are separate from each other) or are only partially overlapped with each other.

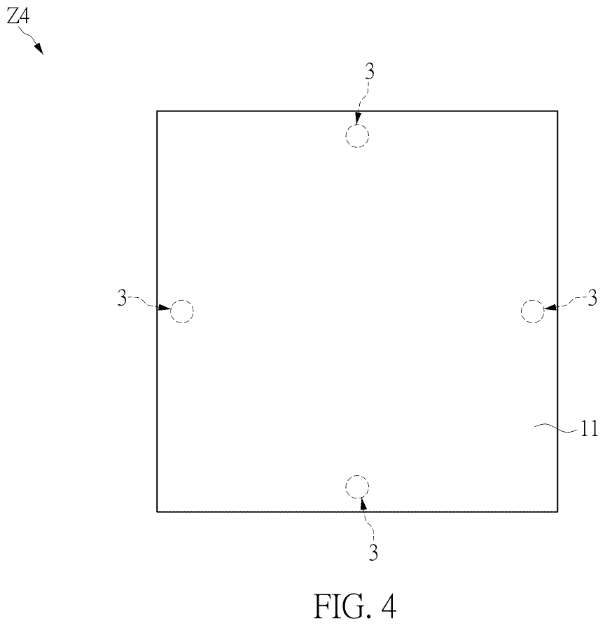

Referring to FIG. 4, FIG. 4 is a top view of a double-sided power device Z4 according to one embodiment of the present disclosure, in which only the first circuit substrate 11 and the plurality of support members 3 are shown. In this embodiment, the support members 3 are cylinders, and a total quantity of the support members 3 is four. When an area of the first circuit substrate 11 is used as a reference, a cross-sectional area of each of the support members 3 in a horizontal cross-section occupies 1% to 5% of the area of the first circuit substrate 11.

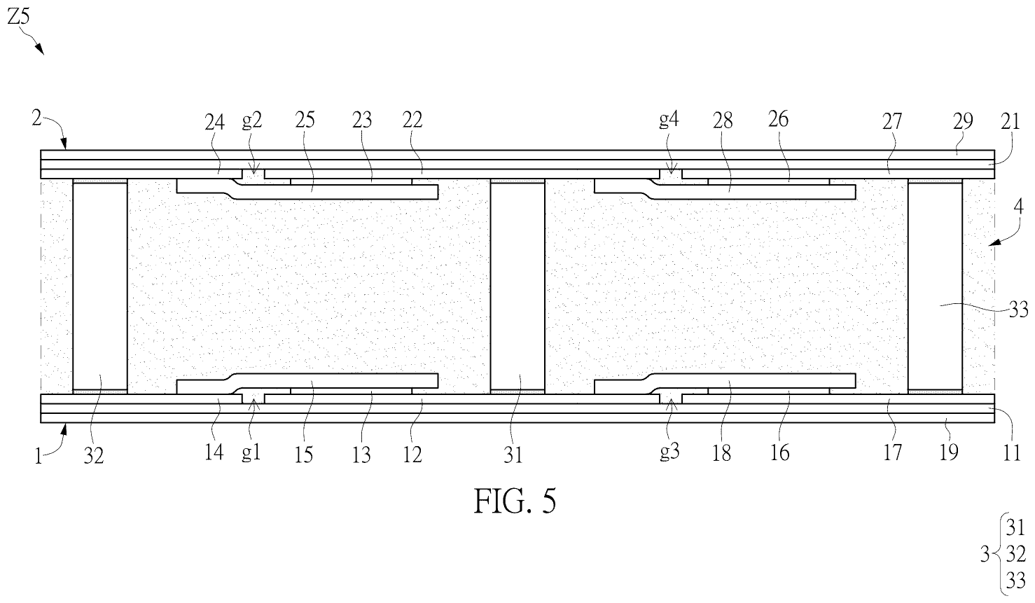

Referring to FIG. 5, FIG. 5 is a schematic side view of a double-sided power device Z5 according to one embodiment of the present disclosure. In this embodiment, the double-sided power device includes a third support member 33. The first power module 1 further includes a third power chip 16, a third electrical connecting element 18, and a fifth conductive layer 17. The third power chip 16 is located on the fifth conductive layer 17. The third electrical connecting element 18 is electrically connected to the third power chip 16 and the first conductive layer 12, respectively. The fifth conductive layer 17 is spaced apart from the first conductive layer 12 by a third gap g3. The second power module 2 further includes a fourth power chip 26, a fourth electrical connecting element 28, and a sixth conductive layer 27. The fourth power chip 26 is located on the sixth conductive layer 27. The fourth electrical connecting element 28 is electrically connected to the fourth power chip 26 and the third conductive layer 22, respectively. The sixth conductive layer 27 is spaced apart from the third conductive layer 22 by a fourth gap g4. The second support member 32 is used as a high-voltage input terminal, the first support member 31 is used as a current output terminal, and the third support member 33 is a grounding terminal. With such structure, the efficiency of power output can be greatly improved.

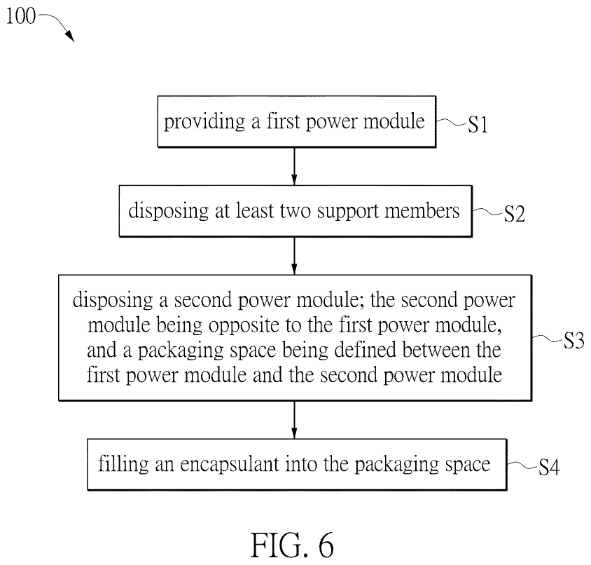

Referring to FIG. 6, in conjunction with FIGS. 1A to 1C, FIG. 6 is a schematic flowchart of a method for manufacturing a double-sided power device 100 according to one embodiment of the present disclosure. The method for manufacturing a double-sided power device 100 includes step S1 to step S4. Step S1 includes: providing a first power module 1. The first power module 1 includes a first circuit substrate 11, a first conductive layer 12, a first power chip 13, a second conductive layer 14, and a first electrical connecting element 15. The first conductive layer 12 is located on the first circuit substrate 11. The first power chip 13 is located on the first conductive layer 12. The second conductive layer 14 is located on the first circuit substrate 11 and spaced apart from the first conductive layer 12 by a first gap g1. The first conductive layer 12 and the second conductive layer 14 have different electrical potentials. Two ends of the first electrical connecting element 15 are electrically connected to the first power chip 13 and the second conductive layer 14, respectively.

Step S2 includes: disposing at least two support members 3. Each of the support members 3 is an electrical conductor. When the quantity of the support members 3 is two, the two support members 3 are respectively defined as a first support member 31 and a second support member 32. One end of the first support member 31 is connected to the first conductive layer 12, and one end of the second support member 32 is connected to the second conductive layer 14. The first support member 31 and the second support member 32 can be connected to the conductive layers (i.e., the first conductive layer 12 and the second conductive layer 14) by welding, ultrasonic bonding, or sintering, and the present disclosure is not limited thereto. It should be noted that, if the connection is made via soldering, a flux is not required.

Step S3 includes: disposing a second power module 2. The second power module 2 is opposite to the first power module 1, and a packaging space S is defined between defined between the first power module 1 and the second power module 2. The second power module 2 includes a second circuit substrate 21, a third conductive layer 22, a second power chip 23, a fourth conductive layer 24, and a second electrical connecting element 25. The third conductive layer 22 is located on the second circuit substrate 21. The second power chip 23 is located on the third conductive layer 22. The fourth conductive layer 24 is located on the second circuit substrate 21 and is space apart from the third conductive layer 22 by a second gap g2. Two ends of the second electrical connecting element 25 are electrically connected to the second power chip 23 and the fourth conductive layer 24, respectively. Another end of the first support member 31 is connected to the third conductive layer 22, and another end of the second support member 32 is connected to the fourth conductive layer 24. Similarly, the first support member 31 and the second support member 32 can be connected to the conductive layers (i.e., the third conductive layer 22 and the fourth conductive layer 24) by welding, ultrasonic bonding, or sintering, and the present disclosure is not limited thereto.

Step S4 includes: filling an encapsulant 4 into the packaging space S. In this way, a double-sided power device according to one embodiment (e.g., the embodiment shown in FIG. 1C) is completed.

### Beneficial Effects of the Embodiments

In conclusion, in the double-sided power device and the method for manufacturing the double-sided power device provided by the present disclosure, by the structural design of the double-sided power device, the support members having electrical conductivity are disposed in the power device, such that the first power module and the second power module are electrically connected. Therefore, the power output by the power modules can be increased in a unit area; for example, the power output can be doubled. Furthermore, by providing the support members, heights of the first power module and the second power module in the vertical direction can be limited.

Moreover, according to certain embodiments, since the support members are metal column or metal walls, the structural strength of the double-sided power device can be enhanced.

In addition, according to certain embodiments, since the support members are metal column or metal walls, the heat-dissipation capability of the double-sided power device can be improved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A double-sided power device, comprising:
a first power module including:
a first circuit substrate;
a first conductive layer located on the first circuit substrate;
a first power chip located on the first conductive layer;
a second conductive layer located on the first circuit substrate and spaced apart from the first conductive layer by a first gap, wherein the first conductive layer and the second conductive layer have different electrical potentials; and
a first electrical connecting element, wherein two ends of the first electrical connecting element are electrically connected to the first power chip and the second conductive layer, respectively;
a second power module, wherein the second power module is opposite to the first power module, a packaging space is defined between the first power module and the second power module, and the second power module includes:
a second circuit substrate;
a third conductive layer located on the second circuit substrate;
a second power chip located on the third conductive layer;
a fourth conductive layer located on the second circuit substrate and spaced apart from the third conductive layer by a second gap; and
a second electrical connecting element, wherein two ends of the second electrical connecting element are electrically connected to the second power chip and the fourth conductive layer, respectively;
at least two support members respectively defined as a first support member and a second support member, wherein two ends of the first support member are electrically connected to the first conductive layer and the third conductive layer, respectively, and two ends of the second support member are electrically connected to the second conductive layer and the fourth conductive layer, respectively; and
an encapsulant filled in the packaging space.

2. The double-sided power device according to claim 1, wherein each of the support members is a column or a wall.

3. The double-sided power device according to claim 1, wherein each of the support members is a tin pillar, and a length of each of the support members in a vertical direction is greater than or equal to 0.5 mm.

4. The double-sided power device according to claim 1, wherein each of the support members is able to withstand a current flow of at least 5 amps.

5. The double-sided power device according to claim 1, wherein a cross-sectional area of each of the support members in a horizontal cross-section occupies 1% to 5% of an area of the first circuit substrate.

6. The double-sided power device according to claim 1, wherein a horizontal plane is defined between the first power module and the second power module, and the first power module is mirror-symmetrical to the second power module via the horizontal plane.

7. The double-sided power device according to claim 1, wherein a projection of the first power chip on the second circuit substrate along a vertical direction defines a projection area, and at least a portion of the second power chip is not located within the projection area.

8. A method for manufacturing a double-sided power device, comprising:
providing a first power module, wherein the first power module includes:
a first circuit substrate;
a first conductive layer located on the first circuit substrate;
a first power chip located on the first conductive layer;
a second conductive layer located on the first circuit substrate and spaced apart from the first conductive layer by a first gap, wherein the first conductive layer and the second conductive layer have different electrical potentials; and
a first electrical connecting element, wherein two ends of the first electrical connecting element are electrically connected to the first power chip and the second conductive layer, respectively;
disposing at least two support members, wherein the at least two support members are respectively defined as a first support member and a second support member, and wherein one end of the first support member is connected to the first conductive layer, and one end of the second support member is connected to the second conductive layer;
disposing a second power module, wherein the second power module is opposite to the first power module, a packaging space is defined between the first power module and the second power module, and the second power module includes:
a second circuit substrate;
a third conductive layer located on the second circuit substrate;
a second power chip located on the third conductive layer;
a fourth conductive layer located on the second circuit substrate and spaced apart from the third conductive layer by a second gap; and
a second electrical connecting element, wherein two ends of the second electrical connecting element are electrically connected to the second power chip and the fourth conductive layer, respectively;
wherein another end of the first support member is connected to the third conductive layer, and another end of the second support member is connected to the fourth conductive layer; and
filling an encapsulant into the packaging space.

9. The method according to claim 8, wherein each of the support members is a column or a wall.

10. The method according to claim 8, wherein each of the support members is a tin pillar, and a length of each of the support members in a vertical direction is greater than or equal to 0.5 mm.

11. The method according to claim 8, wherein each of the support members is able to withstand a current flow of at least 5 amps.

12. The method according to claim 8, wherein a cross-sectional area of each of the support members in a horizontal cross-section occupies 1% to 5% of an area of the first circuit substrate.

13. The method according to claim 8, wherein a horizontal plane is defined between the first power module and the second power module, and the first power module is mirror-symmetrical to the second power module via the horizontal plane.

14. The method according to claim 8, wherein a projection of the first power chip on the second circuit substrate along a vertical direction defines a projection area, and at least a portion of the second power chip is not located within the projection area.
